(19) United States
(12) Patent Application Publication
(10) Pub. No.: US 2001/0008707 A1
(43) Pub. Date: Jul. 19, 2001

(54) PVD process for manufacturing a colored coating insensitive to fingerprints on articles and articles having such a coating

(76) Inventors: Michiel J.J. Eerden, Beuningen (NL); Antonius Petrus Hurkmans, Taylorsville, NC (US); Gerrit Jan van der Kolk, Maarheeze (NL)

Correspondence Address: Douglas W. Sprinkle, Gifford, Krass, Groh, Sprinkle,, Anderson & Citkowski, P.C., 280 N. Old Woodward Ave. Suite 400, Birmingham, MI, 48009, US

(21) Appl. No.: 09/754,228

(22) Filed: Jan. 2, 2001

(30) Foreign Application Priority Data
Jan. 14, 2000 (DE) 100 01 381.3

(51) Int. Cl. B32B 15/00; C23C 14/34

(52) U.S. Cl. 428/615; 204/192.38; 204/192.15; 204/192.16; 428/627; 428/655; 428/656; 428/660; 428/661

(57) ABSTRACT

A PVD process for manufacturing a coating (16, 18, 20, 22, 23) on articles (12), in particular on articles which have a relatively low temperature resistance such as articles made of brass, zinc and plastic, including such with an electroplated coating, wherein a plurality of layers (16, 18, 20, 22) are built up by arc discharge vaporization to manufacture a colored coating insensitive to fingerprints and are selected in order to achieve a color by this kind of coating alone which corresponds as far as possible to the desired end color; and wherein a hard material cover layer (23) is applied to the layer structure by means of cathode or magnetron sputtering or by the simultaneous use of arc discharge vaporization and cathode or magnetron sputtering, said cover layer generating the final color and being limited to the smallest possible layer thickness, preferably to under 500 nm.

The present invention relates to a PVD process for manufacturing a colored coating less sensitive to fingerprints on articles in accordance with the preamble of claim 1 and to articles having such a coating.

A PVD process for coating articles can be seen, for example, from the European patent 439 561 or the corresponding European application 909 09 697. This document describes a PVD process in which the articles to be coated are inserted into a PVD plant designed to execute both arc discharge vaporization and cathode or magnetron sputtering and are first cleaned and etched by an ion etching process generated in the arc discharge mode, a bonding layer is built up on the object by means of arc discharge vaporization and then a further coating is carried out by means of cathode sputtering or magnetron sputtering.

A similar method is described in the European application 99183848.8, with this application being concerned with the generation of multi-layer hard material films for corrosion resistance and abrasion resistance.

It is known, above all in the field of architectural hardware and commodities for general use, to apply decorative coatings onto various materials by means of such PVD processes, with the coatings also being intended to provide hard and corrosion-resistance surfaces. The typical articles under discussion are made of brass, zinc and plastics, frequently having electroplated surfaces. Such materials have a relatively low temperature resistance and must therefore be coated at relatively low temperatures.

One problem with the decorative coating of articles of the said kind by means of PVD processes is the sensitivity of the manufactured coatings to fingerprints. Grease from the fingers of the users tends to penetrate the coating, whereby the fingerprints become visible. The fingerprints created in this way are also difficult to remove as the greasy substances which make the fingerprints visible are located not only on the coating, but also inside the coating.

It is known, for instance, that when carrying out the known kind of PVD sputter coatings at low temperatures, open columnar coating structures are created which, it is assumed, occur because the materials condensing on the surface of the article are mainly neutral atoms. The open, columnar structures favor the entrance of the greasy substances between the columns. Furthermore, the open, columnar structure provides more points of access for a chemical attack on the articles by chemical compounds which are present in the environment and by substances used for cleaning.

With respect to decorative colors made by PVD coatings, a situation can also arise in which the desired color can best be achieved by cathode or magnetron sputtering.

It is the object of the present invention to provide a PVD process for manufacturing a colored coating insensitive to fingerprints on articles, in particular on such articles which have relatively low temperature resistance, such as brass, zinc and plastic, in which, on the one hand, the desired color can be achieved and, on the other, the desired insensitivity to fingerprints is also achieved.

To satisfy said object, there is provided a method in accordance with the invention for manufacturing a coating on articles, in particular on articles having relatively low temperature resistance, such as articles made of brass, zinc and plastic, including such article of this kind with an electroplated coating, wherein the articles to be coated are inserted in a PVD plant designed to carry out both arc discharge vaporization and cathode or magnetron sputtering and are first cleaned and etched by ion etching generated in the arc discharge mode or generated by a plasma source, wherein a bonding layer is built up on the object by means of arc discharge vaporization, wherein a plurality of layers is built up by arc discharge vaporization and selected to manufacture a colored coating insensitive to fingerprints in order to achieve a color by this kind of coating alone which corresponds as far as possible to the desired end color and wherein a hard material cover layer is applied to the layer structure by means of cathode or magnetron sputtering or by the simultaneous use of arc discharge vaporization and cathode or magnetron sputtering, said cover layer generating the final color and being limited to the smallest possible layer thickness, preferably to under 500 nm.

Whereas in the prior art, the desired color is achieved by cathode or magnetron sputtering and by arc discharge vaporization in accordance with EP-B-0 439 561 or the European application 99 183 848.8, it has been discovered in accordance with the invention that coating the articles by means of arc discharge vaporization results in coatings which have a higher density at a comparable temperature level, whereby the occurrence of open, columnar structures is largely suppressed, which is due to the ionized state of the condensing material flux. The problem of fingerprint sensitivity is substantially lower due to the fact that the coating has an increased density. While a columnar structure is still created, the core formation of the columnar structure in the arc discharge vaporization mode results in more columns of smaller diameter and of a rather closed shape. The structure generated in the arc discharge vaporization mode is maintained in the sputtering mode.

In contrast, in the known processes, the arc discharge mode is only used to generate the bonding layer; the further coating is carried out by means of cathode or magnetron sputtering.

It has also been found in accordance with the invention that the desired color can be achieved in almost all cases in spite of this modified procedure if, on the one hand, one selects the appropriate elements for the layer build-up by means of arc discharge vaporization and if magnetron sputtering is only used for the building up of the last layer, which can also be formed in a correspondingly thin manner and normally is under 100 nm. With this thin layer, which can also be manufactured in some cases by combined magnetron sputtering and arc discharge vaporization (and is thus denser than by magnetron sputtering alone), the problem with fingerprints is not so great and any fingerprints which occur can still be removed with appropriate cleansing agents.

It is particularly favorable if the sputtering step is carried out in the presence of argon since the Ar+ ions which are thus created and which bombard the surface of the coating result in a compacting of the free surface of the coating, whereby the sensitivity to fingerprints is further reduced.

It has also been found in accordance with the invention that the process of the invention is particularly suited to realize the color defined by the BHMA (Building Hardware Manufacturers' Association, USA) as “oil rubbed dark bronze” with the BHMA number 613, which was hitherto not realizable by means of PVD processes.

When this color is measured with the method described in CIE Colorimetry, 2nd edition, published on Feb. 15, 1996, with this method having to be carried out in accordance with the provisions of ISO 7724/1 (1984) “Paints and Varnishes”, Colorimetry, Part 1: Principles, or ASTM E 308 (1985) Standard Method for Computing the Colors of Objects by Using the CIE System or ASTM D 2244 (1985) Standard Method for Calculation of Color Differences from Instrumentally Measured Color Coordinates, or DIN 5033 (1980): Farbmessung, Farbmaβzahlen (Colorimetry, Chromaticities), then the following L*, a* and b* values are obtained for BHMA 613:

L*=45 +/−3

a*=5 +/−1.5 and

b*=12 +/−3.

These values were measured using a Minolta CM 2002 spectrophotometer with the following settings:

illuminant: D65

observation condition: 10°

reflecting components included.

However, this color can be realized in accordance with the invention by a Zr layer and then, by the introduction of carbon (C) and nitrogen (N) into the atmosphere of the treatment chamber, a ZrCN layer is built up on the article by means of arc discharge vaporization, with a TiAlZrN layer subsequently being applied as a cover layer by means of cathode or magnetron sputtering to generate the desired end color.

The process is carried out in a particularly preferred manner by a plurality of layers of Zr and ZrCN being alternately applied to the articles prior to the application of the cover layer. All layers can be approx. 0.1 μm thick.

The invention further relates to colored articles insensitive to fingerprints and coated using PVD and defined in more detail in the further claims.

Preferred embodiments of the invention can be found in the claims.

The invention is described in more detail in the following by way of an embodiment and with reference to the drawing in which are shown:

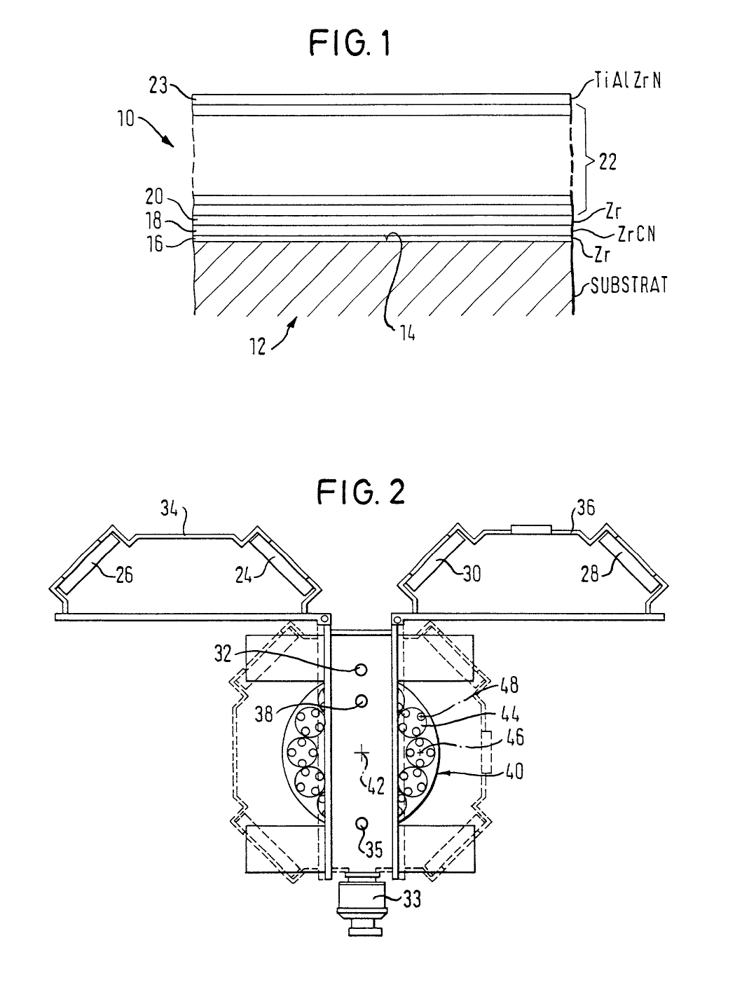

FIG. 1 an example for the layer build-up of a coating in accordance with the invention to generate the BHMA color 613.

FIG. 2 a coating plant in a schematic view which is particularly suited for the carrying out of the method in accordance with the invention;

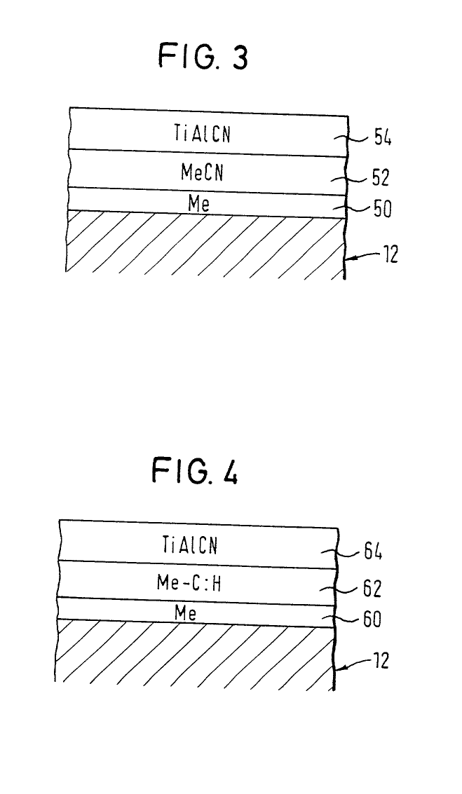

FIG. 3 and FIG. 4 different examples for the generation of the color black.

FIG. 1 shows in a schematic manner an example of a coating in accordance with the invention made of alternating layer sequences 10 to create the BHMA color “oil-rubbed dark bronze” on a substrate 12. The coating in the form of the layer sequence 10 can be applied to any substrate 12.

In this example, a transition layer 16 made of Zr with a thickness in the range of approximately 0.1 μm is located on the surface 14 of the substrate etched by means of an ion etching process using Zr ions.

The ion etching can be carried out with Ar+ ions as an alternative to ion etching with Zr ions.

A layer 18 made of ZrCN with a thickness of approximately 0.05 μm is located on the surface of the transition layer 16 remote from the substrate 12.

This ZrCN layer 18 is followed by a further Zr layer 20, then, alternatingly, a plurality of further ZrCN and Zr layers 22, with approximately 10-30 individual layers being provided in this example which each are normally approximately 0.05 μm thick, with the uppermost layer being a ZrCN layer which can advantageously be somewhat thicker, e.g. 0.1 μm. The total number of alternating Zr/ZrCN layers is not critical.

A cover layer 23 made of TiAlZrN with a thickness of 0.1 to 0.5 μm is located on the uppermost ZrCN layer 18. Whereas the layers 16, 18, 20 and the further layers of the alternating layer sequence 22 are manufactured by means of arc discharge vaporization, the upper cover layer 23 is generated by magnetron sputtering. How these layers are manufactured will now be explained in more detail with reference to FIG. 2.

Instead of using a plurality of alternating layers of Zr and ZrCN, only one Zr layer (approximately 0.1 μm or thicker) could be applied to the substrate and one single layer of ZrCN (between 0.1 μm and 1 μm, normally approximately 0.3 to 0.5 μm thick) could be built up thereon, with these two layers being manufactured by means of arc discharge vaporization. As with the multi-layer arrangement, a TiAlZrN layer with a thickness of 0.1 to 0.5 μm is then applied to the ZrCN layer as a cover layer by means of magnetron sputtering. The desired color “oil-rubbed dark bronze”, i.e. BHMA 613, is also created in this way.

FIG. 2 shows a preferred coating plant suitable for carrying out the method in accordance with the invention.

This plant is illustrated by dashed lines in the closed state and by solid lines with the chamber doors opened or spread apart. The plant shown here, which is basically designed and operated in accordance with European Patent 0 439 561, comprises four targets 24, 26, 28 and 30, with the targets 24 and 26 being held in one chamber wall 34 which can be pivoted open and the targets 28 and 30 being held in the other chamber wall 36 which can be pivoted open.

The targets are in each case rectangular targets which extend in a vertical direction with reference to the drawing and which are operated either in the arc discharge mode or as unbalanced magnetrons to carry out a cathode sputtering process.

Reference symbol 34 indicates a turbo-molecular pump which serves to evacuate the treatment chamber in the closed state.

Reference symbol 36 shows a feedline in schematic form for an inert gas such as argon, while the feedline 38 serves the introduction of the nitrogen required in this example. Acetylene (C₂H₂) can be introduced into the treatment chamber via a further feedline 32.

FIG. 2 further shows a substrate carrier 40 which, on the one hand, rotates around a central axis 42 and, on the other hand, has substrate holders 44 which rotate in turn around their respective axes 46 so that the respectively designed layer formation can be effected by the substrates or articles passing in front of the different targets.

The targets 24, 26 and 28 in this example are made of Zr, while the target 30 consists of TiAl.

The targets 26 and 30 are each operated as unbalanced magnetrons in the method to be described below, while the targets 24, 28 and 32 can be operated in the arc discharge mode.

After the fastening of the substrates to be coated to the substrate holders 40 and the closing of the treatment chamber—which is achieved by pivoting the two doors from the position shown by continuous lines in FIG. 2 into the position shown by dashed lines—the chamber is evacuated via the turbo-molecular pump 34 and argon fed into the treatment chamber via the feedline 36 to form the chamber atmosphere.

Heating is carried out during this process, or shortly afterwards, until the articles 14 have reached a temperature of below 200°C. The generation of Zr ions and Ar ions and thereby the ion etching and ion cleaning of the surfaces of the articles 12 is subsequently provided by the application in a known manner of suitable voltages to one or both targets 24 and 28 and to the substrate carrier 40 or the substrate holders 44. The substrate carrier 40 rotates around the axis 42 during this treatment step. The substrate holders 44 rotate around their own respective axes 46, and, if desired, the individual articles 12 can also be rotated around their own longitudinal axes 48.

All surfaces to be coated of the articles 12, for example door fittings or tap handles, are etched at least substantially uniformly with Zr ions and/or Ar ions in this way and thereby cleaned.

After the etching process has been completed, the targets 24 and 28 made of Zr remain in use, this time in the arc discharge mode, in order to generate the transition layer 16. After the layer 16 made of Zr has been generated, nitrogen N₂ with a little acetylene, for example 10% mass flow, is fed into the atmosphere of the treatment chamber via the feedlines 32 and 38, whereby the first ZrCN layer 18 is created in the arc discharge mode.

After the layer 18 made of ZrCN has been manufactured, the feed of nitrogen via the feedline 38 and the feed of acetylene via the feedline 32 is stopped and argon is again fed into the chamber atmosphere via the feedline 36. The layer 20 made of Zr is manufactured by the continued operation of the targets 24 and 28 in the arc discharge mode. A further layer of ZrCN is built up on the layer 20 by operating the target 32 in the arc discharge mode and by the gas alternation to nitrogen and acetylene via the feedlines 38 and 32 and, by repetition of the process, finally the whole alternating layer sequence 22. All these layers are therefore manufactured in the arc discharge mode. After the layer sequence 22 has been completed, the target 30 made of TiAl and the target 26 made of Zr are now put into operation, this time for the carrying out of cathode sputtering, i.e. the targets 30 and 26 are operated as unbalanced magnetrons. At the same time, nitrogen is fed into the atmosphere of the treatment chamber via the feedline 38, whereby the cover layer 23 made of TiAlZrN is built up, also with a thickness of 0.1 to 0.5 μm, on the free surface of the layer sequence 22. The coating, i.e. the article 12, now has a hard surface with the desired color of oil rubbed dark bronze and has a surface insensitive to fingerprints and preferably also corrosion resistant.

Since the substrates 12 on the substrate holders 44 at the substrate carrier 40 pass through the ion currents of the targets and since the articles 12 are rotated around their own axes 48, around the axes 46 of the substrate holders 44 and around the axis of the substrate carrier 40, a uniform coating of all important surfaces of the articles to be coated is achieved so that the coloration is also smooth and uniform. That is, the rotational movements of the articles are maintained for all cleaning and coating procedures.

After the cover layer 23 has been manufactured, the articles 12 are completely coated and can be removed from the treatment chamber and forwarded for further use.

FIGS. 3 and 4 show alternative possibilities of generating the color black. The following CIE L*, a* and b* values can be given for this color:

a*=0

b*=0

L*=20-70.

This color is generated on a substrate 12 as follows in accordance with FIG. 3:

First, a metal layer 50 is generated which is made of any metal usually used for PVD processes; for example, a layer of Pi, Cr, Zr or W, having a thickness of normally 0.1 μm, with thicker layers also being possible, for example up to 1 μm, although this is not necessary. This metal layer is generated by arc discharge vaporization. A layer 52 made of MeCN is then deposited on this metal layer, with Me standing for a metal, normally the same metal as used for layer 50. This layer 52 is also generated by arc discharge vaporization and usually has a thickness in the range between 0.1 μm and 1 μm, usually 0.3 μm. It makes sense for the metal layer 50 to be deposited in the treatment chamber with an inert gas, for example argon, and for nitrogen and acetylene to be fed into the gas atmosphere of the chamber to generate the MeCN layer.

Subsequently, a cover layer 54 made of TiAlCN is deposited onto the layer 52 by means of magnetron sputtering, with a thickness of up to 1 μm, usually 500 nm or less. The desired color of black, as defined above, is created in this way.

As an alternative to the deposition of a single layer 50 made of metal and a single intermediate layer 52 made of MeCN, a layer sequence of alternating layers of metal and MeCN can be used, as in the example in accordance with FIG. 1, with the individual layers then being thinner and with a layer sequence of a total of 10-30 individual layers being used as before.

The example in accordance with FIG. 4 is realized as follows:

First, a metal layer 60 is here also deposited on the substrate 12 by means of arc discharge vaporization, also with a thickness of normally 0.1 μm, with the layer thickness also being able to be greater than 0.1 μm, for example up to a thickness of approximately 1 μm. The metal can here also consist of any metal normally used for PVD processes, for example, of Ti, Cr, Zr or W.

The layer 62 is then deposited on the layer 60 using the same metal and using the arc discharge vaporization method, with this process being carried out with a relatively high portion of C₂H₂ in the chamber atmosphere so that a metal carbide with integrated hydrogen is created, which is expressed by the designation Me—C:H. This layer 62 usually has, as in the example in FIG. 3, a thickness in the range between 0.1 μm and 1 μm, in particular approximately 0.3 μm. When the layer 62 has been deposited, the cover layer 64 made of TiAlCN is deposited by means of magnetron sputtering. This layer is identical here to layer 54 of the example in FIG. 3. The same data as were given in connection with the layer 54 also apply to this layer.

A layer sequence of 10-30 alternating individual layers can also be deposited instead of a single metal layer 60 and a single Me—C:H layer 62 in this example, with the individual layers then being thinner, for example 0.05 μm thick, with the first and the last layer of the layer sequence advantageously being able to be thicker, e.g. 0.1 μm.

The substrate 12 in all examples can be a temperature-sensitive substrate. The advantage is achieved in all cases that the coating does not only have the desired color and is wear-resistant, but is also insensitive to fingerprints. The color black, as defined above, is generated in all examples in accordance with FIGS. 3 and 4.

1. A PVD process for manufacturing a coating (16, 18, 20, 22, 23; 50, 52, 54; 60, 62, 64) on articles (12), in particular on articles which have a relatively low temperature resistance such as articles made of brass, zinc and plastic, including such with a galvanic layer, wherein the articles to be coated are inserted in a PVD plant (FIG. 2) designed to carry out both arc discharge vaporization and cathode or magnetron sputtering and are first cleaned and etched by ion etching generated in the arc discharge mode or generated by a plasma source, a bonding layer (16, 50, 60) is built up on the article by means of arc discharge vaporization and then a further coating (23; 54; 64) is carried out by means of cathode or magnetron sputtering, characterized in that a plurality of layers (16, 18, 20, 22; 50, 52; 60, 62) are built up by arc discharge vaporization to manufacture a colored coating insensitive to fingerprints and are preferably selected in order to achieve a color by this kind of coating alone which corresponds as far as possible to the desired end color; and in that a hard material cover layer (23; 54; 64) is applied to the layer structure by means of cathode or magnetron sputtering or by the simultaneous use of arc discharge vaporization and cathode or magnetron sputtering, said cover layer generating the final color and being limited to the smallest possible layer thickness, preferably to under 500 nm.

2. A process in accordance with claim 1, characterized in that the sputtering step is carried out in the presence of argon in order to achieve a compacting of the free surface of the coating by the bombardment with Ar+ ions.

3. A process in accordance with claim 1, characterized in that to achieve the color defined by the BHMA as “oil-rubbed dark bronze”, first a Zr layer (16) and then, by the introduction of carbon (C) and nitrogen (N) into the atmosphere of the treatment chamber, a ZrCN layer (18) is built up on the article (12) by means of arc discharge vaporization; and in that a TiAlZrN layer (23) is subsequently applied as a cover layer by means of cathode or magnetron sputtering to generate the desired end color.

4. A process in accordance with claim 3, characterized in that a plurality of layers (16, 18, 20, 22) made of Zr and ZrCN are alternately applied to the articles prior to the application of the cover layer (23).

5. A process in accordance with claim 4, characterized in that all alternating layers, with the exception of the first and the last layers, are approximately 0.05 μm thick.

6. A process in accordance with claim 1, characterized in that to achieve the color black, one of the following layer variations is used:
a) a first layer (50) made of a metal usually used for PVD processes;
a second layer (52) made of MeCN, with the metal (Me) preferably being the same metal as is used for the first layer (50); and the first and second layers are generated by arc discharge vaporization; and a cover layer (54) made of TiAlCN, which is generated by magnetron sputtering;
b) a layer arrangement as given at a), but with a plurality of alternating layers made of metal and MeCN;
c) a first layer (60) made of a metal which is usually used for PVD processes, a second layer (62) made of Me—C:H, with the metal (Me) preferably being the same metal that is used for the first layer (60); and these first and second layers (60, 62) are generated by arc discharge vaporization and a cover layer made of TiAlCN, which is generated by magnetron sputtering; and
d) a layer arrangement as at c), but with a plurality of alternating layers made of metal and ME—C;H.

7. A colored article (12), insensitive to fingerprints and coated by means of PVD, consisting of a temperature-sensitive material such as brass, zinc and plastic, including such a material with a galvanic coating, in particular for decorative purposes such as building hardware or water-conducting fittings, wherein the article (12) has at least two layers (16, 18; 50, 52; 60, 62) generated by arc discharge vaporization, and preferably a plurality of such layers, which preferably result at least substantially in the desired end color; and wherein the end color of the surface of the article is formed by an uppermost cover layer (23; 54; 64) which is generated by cathode or magnetron sputtering or by combined arc discharge vaporization and cathode or magnetron sputtering, with the cover layer having the smallest possible thickness and preferably being less than 500 nm.

8. An article in accordance with claim 7 in the color 613 defined by the BHMA, characterized in that the coating consists of a Zr layer (16) and at least one ZrCN layer (18), preferably of a plurality of alternating Zr and ZrCN layers (16, 18, 20, 22), which are deposited onto the article by arc discharge vaporization; and in that the cover layer (23) consists of TiAlZrN and is applied to the article by means of cathode or magnetron sputtering or by means of cathode or magnetron sputtering in combination with arc discharge vaporization.

9. An article in accordance with claim 8, characterized in that, in the case of a plurality of alternating Zr and ZrCN layers (16, 18, 20, 22), all these layers, with the exception of the first and the last ones, are approximately 0.05 μm thick.

10. An article in accordance with claim 7, characterized in that it has the color black, which is realized by one of the following layer arrangements:
a) a first layer (50) made of a metal usually used for PVD processes;
a second layer (52) made of MeCN, with the metal (Me) preferably being the same metal as is used for the first layer (50); and the first and second layers being generated by arc discharge vaporization; and a cover layer (54) made of TiAlCN, which is generated by magnetron sputtering;
b) a layer arrangement as given at a), but with a plurality of alternating layers made of metal and MeCN;
c) a first layer (60) made of a metal which is usually used for PVD processes; a second layer (62) made of Me—C:H, with the metal (Me) preferably being the same metal that is used for the first layer (60); and these first and second layers (60, 62) being generated by arc discharge vaporization and a cover layer made of TiAlCN, which is generated by magnetron sputtering; and
d) a layer arrangement as at c), but with a plurality of alternating layers made of metal and ME—C;H.
